(19) United States
(12) Patent Application Publication
(10) Pub. No.: US 2025/0201694 A1
(43) Pub. Date: Jun. 19, 2025

(54) SEMICONDUCTOR DEVICE

(71) Applicant: Renesas Electronics Corporation, Tokyo (JP)

(72) Inventor: Norikazu MOTOHASHI, Tokyo (JP)

(21) Appl. No.: 18/931,216

(22) Filed: Oct. 30, 2024

(30) Foreign Application Priority Data
Dec. 15, 2023 (JP) 2023-212289

(51) Int. Cl. H01L 23/498; H01L 23/00; H01L 23/31; H01L 23/367

(52) U.S. Cl. CPC H01L 23/49838; H01L 23/3185; H01L 23/3675; H01L 23/49822; H01L 24/16; H01L 2224/16227; H01L 2924/18161; H01L 2924/35121

(57) ABSTRACT

A semiconductor device including: a semiconductor chip mounted on a wiring substrate such that a main surface of the semiconductor chip faces a front surface of an insulating film of the wiring substrate; and a bump electrically connecting a land and an electrode pad. Here, in cross-sectional view, a center of the land is shifted in a direction from a center of an opening portion, which exposes a part of the land, of the insulating film toward a center of the semiconductor chip is provided.

### CROSS-REFERENCE TO RELATED APPLICATIONS

The disclosure of Japanese Patent Application No. 2023-212289 filed on Dec. 15, 2023, including the specification, drawings and abstract is incorporated herein by reference in its entirety.

### BACKGROUND

This disclosure relates to a semiconductor device.

There are disclosed techniques listed below.
[Patent Document 1] Japanese Unexamined Patent Application Publication No. 2022-191691

There is a technology for mounting a semiconductor chip on a wiring substrate by a flip-chip connection method (or face-down mounting method) (see, for example, Patent Document 1). In a semiconductor device adopting the flip-chip connection method, the semiconductor chip and the wiring substrate are electrically connected with each other through a plurality of bumps made of, for example, solder material. Such a semiconductor device is also referred to as FCBGA (Flip Chip Ball Grid Array).

### SUMMARY

In recent years, there has been an increasing demand for the miniaturization of a semiconductor device. Therefore, the distance between two bumps (namely, lands to which bumps are connected) adjacent to each other tends to decrease. On the other hand, when the semiconductor device adopting the flip-chip connection method is mounted on a motherboard, a crack may occur in an insulating film of the wiring substrate composing the semiconductor device, due to the heat treatment in a mounting step of the semiconductor device. Here, the term “crack” includes the interfacial delamination between the land and the insulating film. It has been found that if the crack occur in the insulating film, the solder material composing the bump melted by the heat treatment may flow into the cracked part, and thus, there is a possibility of causing a short circuit between two lands (or between a land and a wiring provided in the vicinity of this land) adjacent to each other.

Other objects and novel features will become apparent from the description of this specification and the accompanying drawings.

A semiconductor device according to one embodiment includes a land having a center which is shifted in a direction from a center of an opening portion, which exposes a part of the land, of an insulating film toward a center of a semiconductor chip in plan view.

According to the embodiment, an adhesion area between the land in the direction (center direction) and the insulating film can be increased, thereby it is possible to provide a semiconductor device that can improve the delamination resistance of the insulating film.

### BRIEF DESCRIPTION OF THE DRAWINGS

FIG. 1 is an upper surface view of a semiconductor device according to an embodiment.

FIG. 2 is a lower surface view of the semiconductor device shown in FIG. 1.

FIG. 3 is a view schematically showing a wiring substrate and the semiconductor chip mounted on the wiring substrate according to the embodiment.

FIG. 4 is a cross-sectional view along line A-A in FIG. 1.

FIG. 5 is a surface view of the semiconductor chip showing a crack occurrence situation in an insulating film of the wiring substrate according to the embodiment.

FIG. 6 is a plan view showing a center of each of a bump and a land related to Structure 1 according to the embodiment.

FIG. 7 is a plan view showing a center of each of a bump and a land related to Structure 2 and Related Structure of according to the embodiment.

FIG. 8 is a cross-sectional view showing the center of each of the bump and the land related to Structure 2 and Related Structure of according to the embodiment.

FIG. 9A is a cross-sectional view showing a “Pad on Via structure”.

FIG. 9B is a cross-sectional view showing a “Pad on Stacked Via structure”.

FIG. 9C is a cross-sectional view showing a “Pad on Stacked Via structure directly connected to a core layer”.

### DETAILED DESCRIPTION

### Embodiment

Hereinafter, an embodiment of the invention will be described with reference to the drawings. However, the invention claimed in the claims is not limited to the following embodiments. Furthermore, not all configurations described in the embodiments are essential as means for solving the problems. For clarity of explanation, the following description and drawings are appropriately omitted and simplified. In each drawing, the same elements are designated by the same reference numerals, and redundant descriptions are omitted as necessary.

### (Description of Connection Between Wiring Substrate and Semiconductor Chip According to First Embodiment)

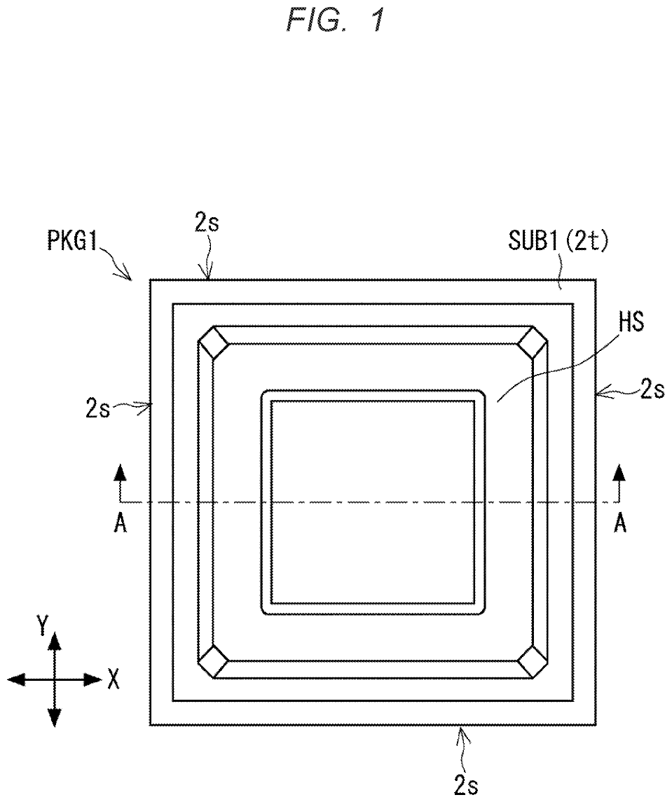

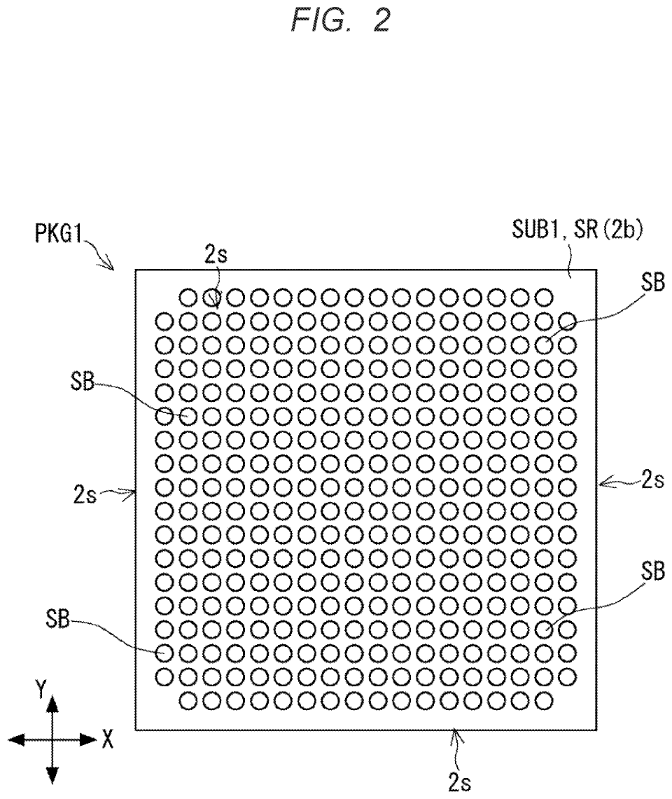

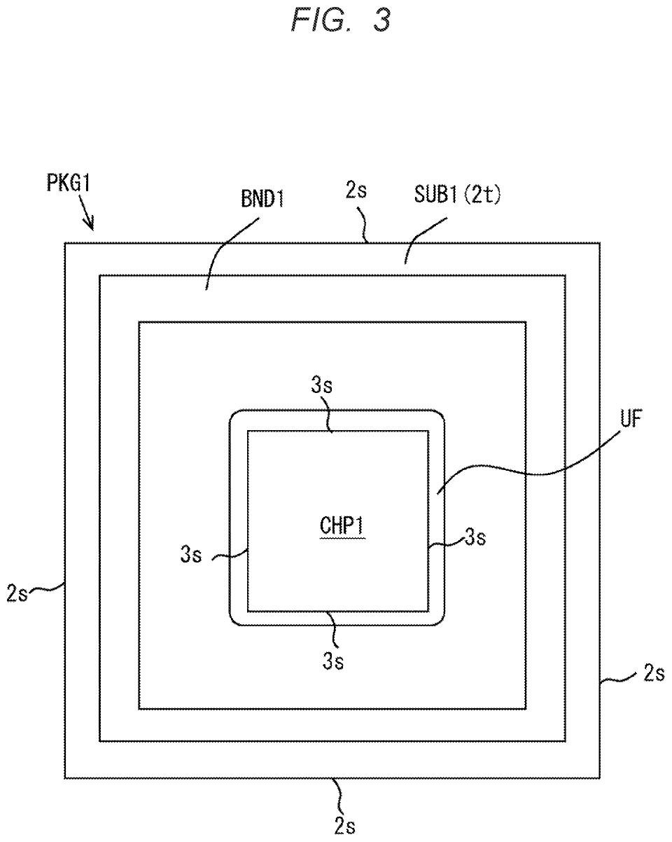

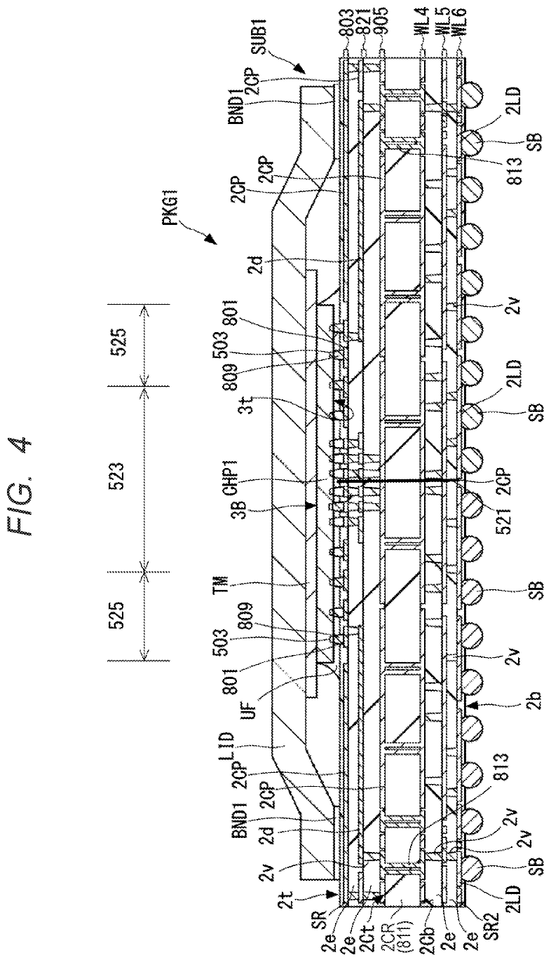

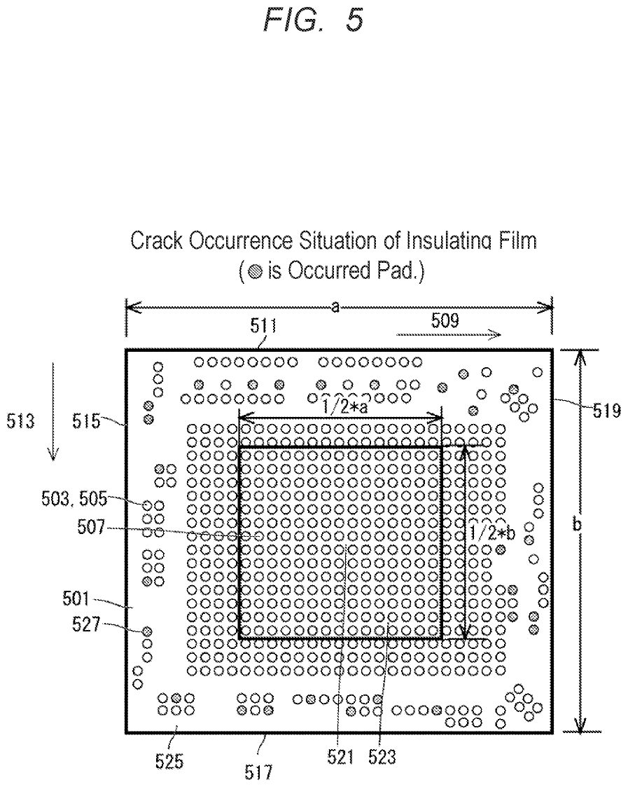

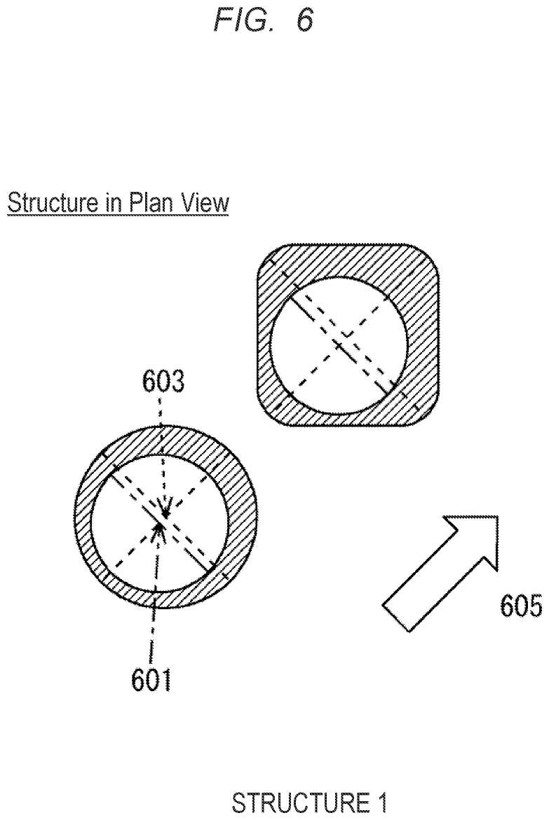

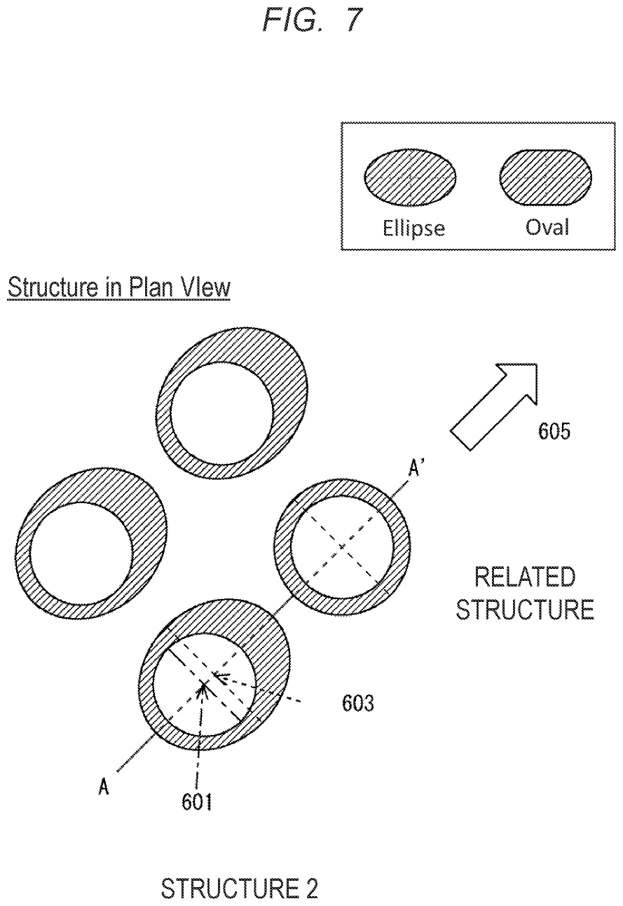

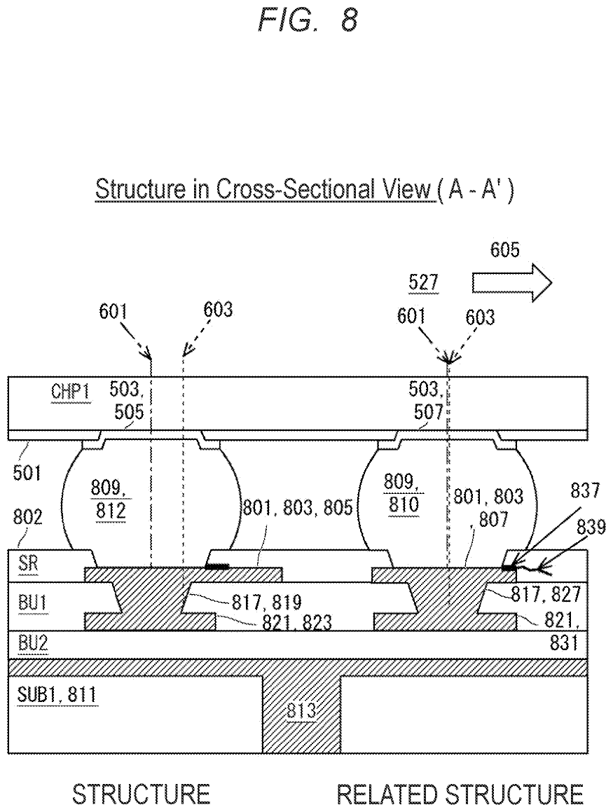

FIG. 1 is an upper surface view of a semiconductor device according to an embodiment. FIG. 2 is a lower surface view of the semiconductor device shown in FIG. 1. FIG. 3 is a view schematically showing a wiring substrate and the semiconductor chip mounted on the wiring substrate according to the embodiment. FIG. 4 is a cross-sectional view along line A-A in FIG. 1. FIG. 5 is a surface view of the semiconductor chip showing a crack occurrence situation in an insulating film of the wiring substrate according to the embodiment. FIG. 6 is a plan view showing a center of each of a bump and a land related to Structure 1 according to the embodiment. FIG. 7 is a plan view showing a center of each of a bump and a land related to Structure 2 and Related Structure of according to the embodiment. FIG. 8 is a cross-sectional view showing the center of each of the bump and the land related to Structure 2 and Related Structure of according to the embodiment. The wiring substrate and the semiconductor chip according to the first embodiment will be described with reference to FIGS. 1 to 8.

A semiconductor device PKG1 of the present embodiment has a wiring substrate SUB1 and a semiconductor chip CHP1 mounted on the wiring substrate SUB1 (see FIG. 3). Furthermore, the semiconductor device PKG1 has a heat dissipation plate TIM arranged on the semiconductor chip CHP1, and a cover member LID covering the entirety of the semiconductor chip CHP1, the entirety of the heat dissipation plate TIM, and a part of the wiring substrate SUB1. Although not shown, the technology described below can also be applied to a semiconductor device that does not have the heat dissipation plate TIM and the cover member LID.

As shown in FIG. 4, the wiring substrate SUB1 has an upper surface (surface, main surface, chip mounting surface, front surface) 2t on which the semiconductor chip CHP1 is mounted, and a lower surface (surface, main surface, mounting surface) 2b located on the opposite side of the upper surface 2t. Moreover, the wiring substrate SUB1 has a plurality of side surfaces 2s (see FIGS. 1 to 3) which respectively continuous with outer edges of each of the upper surface 2t and the lower surface 2b. In case of the present embodiment, each of the upper surface 2t (see FIG. 1) and the lower surface 2b (see FIG. 2) of the wiring substrate SUB1 is formed in square. The upper surface 2t is a chip mounting surface facing a surface 3t of the semiconductor chip CHP1.

The wiring substrate SUB1 has a plurality of wiring layers (6 layers in the example shown in FIG. 4) 803, 821, 905, WL4, WL5, and WL6 that electrically connect a terminal (land 801) arranged on the upper surface 2t, which is the chip mounting surface, and a terminal (land 2LD) arranged on the lower surface 2b, which is the mounting surface. Each wiring layer is located between the upper surface 2t and the lower surface 2b. Each wiring layer has a conductor pattern such as a wiring that serve as a path for supplying an electric signal, an electric power, etc. An insulating layer 2e is arranged between the wiring layers. The wiring layers are electrically connected with each other through an interlayer conductive path that is a via wiring 2v or a through-hole wiring 813, which are penetrating through the insulating layer 2e. In the present embodiment, a wiring substrate including six wiring layers is shown as an example of the wiring substrate SUB1, but the number of wiring layers provided in the wiring substrate SUB1 is not limited to the six wiring layers. For example, a wiring substrate including five wiring layers or less, or more than seventh wiring layers, can be used as a modified example.

Furthermore, among a plurality of wiring layers, the wiring layer 803 located closest to the upper surface 2t is covered with an organic insulating film SR. The organic insulating film SR has an opening portion, and a plurality of lands 801 provided in the wiring layer 803 is exposed from the organic insulating film SR at the opening portion. Moreover, among the plurality of wiring layers, the wiring layer WL6 located closest to the lower surface 2b of the wiring substrate SUB1 has a plurality of lands 2LD, and the wiring layer WL6 is covered with an organic insulating film SR2. Each of the organic insulating film SR and the organic insulating film SR2 is a solder resist film. The plurality of lands 801 provided in the wiring layer 803 and the plurality of lands 2LD provided in the wiring layer WL6 are electrically connected with each other through a conductor pattern (wiring 2d and large-area conductor pattern) provided in each wiring layer of the wiring substrate SUB1, a via wiring 2v, and a through-hole wiring 813. respectively.

Each of the wiring 2d, the land 801, the via wiring 2v, the via land, the through-hole wiring 813, the land 2LD, and the conductor pattern 2CP is made of, for example, copper or a metal material mainly comprised of copper.

Furthermore, the wiring substrate SUB1 is formed on both the upper surface 2Ct and the lower surface 2Cb of an insulating layer (core material, core insulating layer) 2CR made of, for example, a prepreg impregnated with a resin on a glass fiber by stacking the plurality of wiring layers with a build-up method. Moreover, the wiring layer 905 provided on the upper surface 2Ct of the insulating layer 811 and the wiring layer WL4 provided on the lower surface 2Cb are electrically connected with each other through a plurality of through-hole wirings 813 respectively filled with a plurality of through-holes penetrating from one of the upper surface 2Ct and the lower surface 2Cb to the other.

In the example shown in FIG. 4, the wiring substrate SUB1 shows a wiring substrate stacked with a plurality of wiring layers on both the upper surface 2Ct side and the lower surface 2Cb of the insulating layer 811, which is a core material. However, as a modified example to FIG. 4, it is also possible to use a so-called coreless substrate formed by sequentially stacking an insulating layer 811 and a conductor pattern such as wiring 2d, without having the insulating layer 811 made of a rigid material such as prepreg material. When using a coreless substrate, the through-hole wiring 813 is not formed, and each wiring layer is electrically connected with each other through the via wiring 2v.

Furthermore, in the example shown in FIG. 4, a solder ball (solder material, external terminal, electrode, external electrode) SB is connected to each of the plurality of lands 2LD. The solder ball SB is a conductive member that electrically connects the plurality of terminals (not shown) on the motherboard and the plurality of lands 2LD with each other when mounting the semiconductor device PKG1 on the motherboard not shown. The solder ball SB is made of a solder material containing lead (Pb), such as Sn—Pb solder, or a so-called lead-free solder that does not substantially contain Pb. The example of the lead-free solder includes, for example, tin (Sn) only, tin-bismuth (Sn—Bi), tin-copper-silver (Sn—Cu—Ag), tin-copper (Sn—Cu), and the like. Here, the lead-free solder means that the content of lead (Pb) is 0.1 wt % or less, and this content is defined as the standard of the RoHS (Restriction of Hazardous Substances) directive.

Furthermore, as shown in FIG. 2, a plurality of solder balls SB is arranged in a matrix form. Although not shown in FIG. 2, a plurality of lands 2LD (refer to FIG. 4) to which a plurality of solder balls SB is connected is also arranged in a matrix form. Thus, the semiconductor device that arranges a plurality of external terminals (solder balls SB, lands 2LD) in a matrix form on the mounting surface of the wiring substrate SUB1 is called an area array type semiconductor device. The area array type semiconductor device is preferable in that it can effectively utilize the mounting surface (lower surface 2b) of the wiring substrate SUB1 as a space for arranging external terminals, thereby suppressing an increase in the mounting area of the semiconductor device even if the number of external terminals increases. In other words, it is possible to mount a semiconductor device, which increases the number of external terminals due to higher functionality and higher integration, in a space-saving manner.

Furthermore, the semiconductor device PKG1 includes a semiconductor chip CHP1 mounted on the wiring substrate SUB1. As shown in FIG. 4, the semiconductor chip CHP1 has a surface (main surface, upper surface) 3t on which a plurality of bumps 809 is arranged, and a back surface (main surface, lower surface) 3b located on opposite side of the surface 3t. The semiconductor chip CHP1 also includes a plurality of side surfaces 3s each intersecting with the surface 3t and the back surface 3b. As shown in FIG. 3, the semiconductor chip CHP1 is comprised of a quadrangular shape having an area smaller than an area of the wiring substrate SUB1 in plain view. In the example shown in FIG. 3, the semiconductor chip CHP1 is mounted in the central portion of the upper surface 2t of the wiring substrate SUB1, and the four side surfaces 3s of the semiconductor chip CHP1 extend along the four side surfaces 2s of the wiring substrate SUB1, respectively.

Furthermore, a plurality of pad electrodes (pads, electrode pads, bonding pads) 503 is formed on the surface 3t side of the semiconductor chip CHP1. In the example shown in FIG. 4, the semiconductor chip CHP1 is mounted on the wiring substrate SUB1 in a state where the surface 3t faces the upper surface 2t of the wiring substrate SUB1. Such a mounting method is called a face-down mounting method or a flip-chip connection method.

Although not shown, a plurality of semiconductor elements (circuit element) is formed in the semiconductor chip CHP1 at the main surface (specifically, the semiconductor element formation region provided on the element formation surface of the semiconductor substrate, which is the base material of the semiconductor chip CHP1). The plurality of pad electrodes 503 is electrically connected with a plurality of semiconductor elements through a wiring (not shown) formed in the wiring layer located an inside of the semiconductor chip CHP1 (specifically, between the surface 3t and an unillustrated semiconductor element formation region).

The semiconductor chip CHP1 (specifically, the substrate of the semiconductor chip CHP1) is made of, for example, silicon (Si). Furthermore, an insulating film (passivation film) covering the substrate and the wiring of the semiconductor chip CHP1 is formed on the surface 3t, and a part of each of the plurality of pad electrodes 503 is exposed from the passivation film at an opening portion formed in the passivation film. Moreover, the plurality of pad electrodes 503 is made of metal. In the present embodiment, the plurality of pad electrodes 503 is made of, for example, aluminum (Al).

Furthermore, as shown in FIG. 4, the bumps 809 are connected to the plurality of pad electrodes 503, and the plurality of pad electrodes 503 of the semiconductor chip CHP1 and the plurality of lands 801 of the wiring substrate SUB1 are electrically connected with each other through the plurality of bumps 809, respectively. As a solder material, the lead-containing solder or the lead-free solder can be used, similar to the aforementioned solder balls SB. Moreover, the present embodiment employs a so-called solder bump, which is a columnar electrode made of nickel (Ni) or a micro solder ball formed on the pad electrode 503 through an underlying metal film.

Furthermore, as shown in FIG. 4, an underfill resin (insulating resin) UF is located between the semiconductor chip CHP1 and the wiring substrate SUB1. The underfill resin UF is arranged to fill the space between the surface 3t of the semiconductor chip CHP1 and the upper surface 2t of the wiring substrate SUB1. Each of the plurality of bumps 809 is sealed with the underfill resin UF. Moreover, the underfill resin UF, made of insulating (non-conductive) material (for example, a resin material), is arranged to seal the electrical connecting portion (connecting portion of each of the plurality of bumps 809) between the semiconductor chip CHP1 and the wiring substrate SUB1. Thus, by covering the connecting portions between the plurality of bumps 809 and the plurality of lands 801 with the underfill resin UF, it is possible to alleviate the stress occurring at the electrical connecting portion between the semiconductor chip CHP1 and the wiring substrate SUB1. It is also possible to alleviate the stress occurring at the connecting portions between the plurality of pad electrodes 503 of the semiconductor chip CHP1 and the plurality of bumps 809. Furthermore, it is also possible to protect the main surface on which the semiconductor elements (circuit elements) of the semiconductor chip CHP1 are formed.

A cover member (lid, heat spreader, heat dissipation member) LID is arranged on the back surface 3b of the semiconductor chip CHP1. The cover member LID is, for example, a metal plate with a higher thermal conductivity than the wiring substrate SUB1, and has a function to discharge heat generated in the semiconductor chip CHP1 to the outside. Moreover, the cover member LID is thermally connected to the semiconductor chip CHP1 through a heat dissipation plate TIM. The heat dissipation plate TIM is in contact with each of the semiconductor chip CHP1 and the cover member LID.

The cover member LID is adhered to the front surface of the insulating film SR of the wiring substrate SUB1. “BND1” is the adhesive region between the cover member LID and the wiring substrate SUB1. The cover member LID includes the heat dissipation plate. Moreover, the heat dissipation plate is formed of a material containing copper.

As shown in FIG. 3, a center of the semiconductor chip CHP1 does not have to be coaxial with a center of the wiring substrate SUB1, but considering the placement space, it is preferable that they are coaxial with each other. When mounting the semiconductor chip CHP1 on the wiring substrate SUB1, some misalignment may occur depending on the mounting method and the apparatus used in the step. Therefore, in the present embodiment, although described as “coaxial,” this term is used not only when each center is perfectly aligned, but also in case where they are partially overlapping with each other (i.e., “substantially coaxial”).

As shown in FIG. 5, the semiconductor chip CHP1 has a main surface 501 and a plurality of electrode pads 503 arranged on the main surface 501. The semiconductor chip CHP1 is mounted on the wiring substrate SUB1 such that the main surface faces the front surface 802 (shown in FIG. 8) of the insulating film of the wiring substrate.

As shown in FIG. 5, the main surface 501 of the semiconductor chip CHP1 has a first side 511 extending in a first direction 509 in plan view. The main surface 501 of the semiconductor chip CHP1 also has a second side 515 extending in a second direction 513 crossing the first direction 509. Furthermore, the main surface 501 of the semiconductor chip CHP1 has a third side 517 extending in the first direction 509 and facing the first side 511. Additionally, the main surface 501 of the semiconductor chip CHP1 has a fourth side 519 extending in the second direction 513 and facing the second side 515. That is, the main surface 501 of the semiconductor chip CHP1 may be a parallelogram, a rectangle, or a square, but preferably, it is a rectangle.

As shown in FIG. 8, the semiconductor chip CHP1 and the wiring substrate SUB1 are coupled with each other by the plurality of bumps 809. The plurality of electrode pads 503 of the semiconductor chip CHP1 and the plurality of lands 801 of the wiring substrate SUB1 are electrically connected with each other through the plurality of bumps 809, respectively. The electrode pads 503 is a terminal of the semiconductor chip CHP1. The land 801 is a terminal provided in the first wiring layer 803, which is the uppermost wiring layer, of the wiring substrate SUB1. The insulating film SR covers a peripheral portion of each of the plurality of lands 801 so as to expose a part of each of them. The insulating film SR is an insulating film that protects the lands 801, known as a solder resist.

As shown in FIGS. 7 and 8, the center 601 of the opening portion and the center 603 of the land in the related structure of the bump and the land which is a connecting portion between the semiconductor chip CHP1 and the wiring substrate SUB1 are coincided with each other. Therefore, when performing the heat treatment in order to mount the wiring substrate SUB1 on which the semiconductor chip CHP1 is mounted on the motherboard, the crack 839 directed toward the center of the semiconductor chip CHP1 is generated at the contacting portion 837 of the insulating film covering the land 801, as shown in FIG. 5.

As shown in FIG. 5 (and FIG. 4), in plan view, the main surface 501 of the semiconductor chip CHP1 is divided into a central region 523 including the center 521 of the semiconductor chip and a peripheral region 525 arranged around the central region 523. In plan view, the plurality of electrode pads 503 is arranged along the first side 511 and arranged in plural rows. That is, the electrode pads 503 are arranged in a matrix or a similar configuration.

The aforementioned crack tends to occur in the region of the insulating film SR that overlaps with the peripheral region 525 of the semiconductor chip CHP1. For instance, the crack may occur at the electrode pad 527. The reason is considered that the semiconductor chip CHP1, the wiring substrate SUB1, and the underfill resin UF filled between them are expanded during the heat treatment when mounting the semiconductor device PKG1 on the motherboard. At this time, for example, the coefficient of linear expansion of the semiconductor chip CHP1 made of silicon (Si), the coefficient of linear expansion of the wiring substrate SUB1 having an insulating layer (including the core layer) made of glass epoxy resin material, and the coefficient of linear expansion of the underfill resin UF filled between them are different from each other. Therefore, when the wiring substrate SUB1 expands, the land 801 electrically connected with the electrode pad 505 located in the peripheral region 525 of the semiconductor chip CHP1 is pulled in the direction towards the peripheral portion of the wiring substrate SUB1. As a result, it is considered that the crack occur at a portion located on the side, where is closer to the center of the wiring substrate SUB1 (namely, where is closer to the center of the semiconductor chip CHP1) than the center of the land 801, among the insulating film SR covering the peripheral portion of the land 801 so as to expose a part of the land 801.

In particular, the crack occurs at an outside of the region enclosed by a quarter of the distance from the center 521 of the semiconductor chip CHP1 to the first side 511 and a quarter of the distance from the center 521 to the second side 515. In other words, the crack does not occur in the region enclosed by half of the first side 511 (1/2×a) and half of the second side 515 (1/2×b) of the semiconductor chip CHP1 including the center 521 (namely, central region 523), but occurs in the outer region (namely, peripheral region 525).

The connection method disclosed herein, as shown in FIG. 8, features the center 603 of the land being misaligned with the center of the bump. That is, the center 603 of the land is misaligned with the center 601 of the opening portion. The center 601 of the opening portion is shifted towards the direction of the center of the chip. In particular, as shown in FIG. 4, it is preferable to shape the land located in the region of the wiring substrate SUB1 that overlaps with the peripheral region 525 of the semiconductor chip CHP1 in such a manner. That is, in plan view, the center 603 of the land is shifted in a direction 605 from the center 601 of the opening portion, which exposes a part of the land 801, of the insulating film SR toward the center of the semiconductor chip CHP1.

Furthermore, as shown in FIG. 7, the shape of the land 801 may be oval. For example, the shape of the land 801 may be ellipse or oblong. The center 603 of this land is shifted in a direction 605 towards the center of the semiconductor chip CHP1 such that the long axis of the oval shape is aligned with the direction towards the center of the chip.

As shown in FIG. 8, in cross-sectional view, the wiring substrate SUB1 includes a first wiring layer 803 in which a land 801 is provided, an insulating layer BU1 located below the first wiring layer 803, and a second wiring layer 821 located below the insulating layer BU1. The wiring substrate SUB1 has an insulating film SR made of, for example, solder resist, on the first wiring layer 803. Furthermore, the wiring substrate SUB1 includes a plurality of via wirings 817 provided in the insulating layer BU1, and a plurality wirings, which is respectively connected with the plurality of lands 801 through the plurality of via wirings 817, provided in the second wiring layer 821.

The plurality of electrode pads 503 includes a first electrode pad 507 arranged in the central region 523, and a second electrode pad 505 arranged in the peripheral region 525. The plurality of lands 801 includes a first land 807 that is electrically connected with the first electrode pad 507 through a first bump 810 of the plurality of bumps 809, and a second land 805 that is electrically connected with the second electrode pad 505 through a second bump 812 of the plurality of bumps 809.

The plurality of wirings includes a first-layer first wiring 831 that is electrically connected with the first land 807 through a first via wiring 827 of the plurality of via wirings 817, and a first-layer second wiring 823 that is electrically connected with the second land 805 through a second via wiring 819 of the plurality of via wirings 817.

Herein, the second electrode pad 505, the second bump 812, the second land 805, the second via wiring 819, and the first-layer second wiring 823 overlap with each other, in cross-sectional view.

By doing so, it is possible to increase the adhesion area between the land in the center direction of the semiconductor chip and the insulating film, thereby it is possible to improve the delamination resistance of the insulating film.

### (Description of Connection Between Wiring Substrate and Semiconductor Chip According to Second Embodiment)

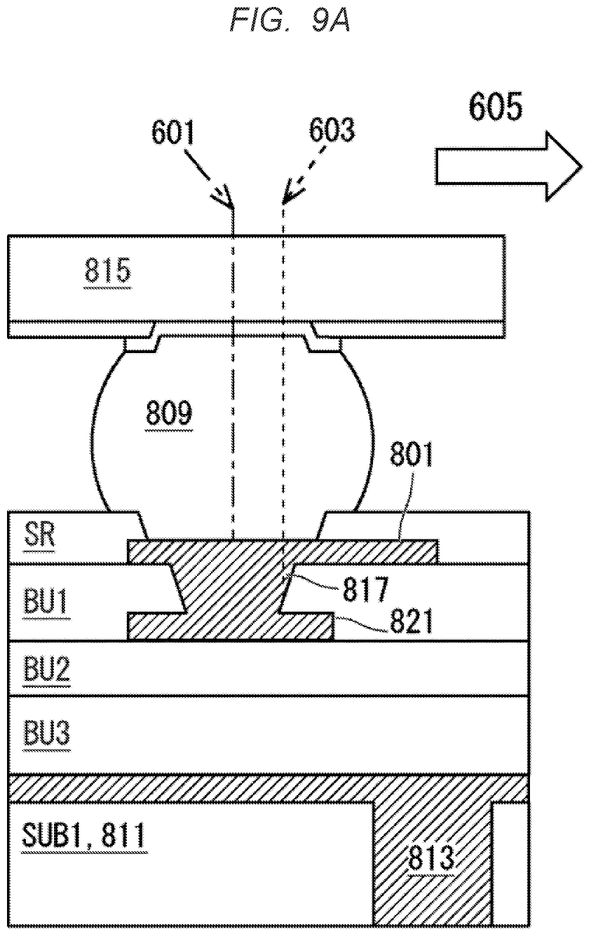

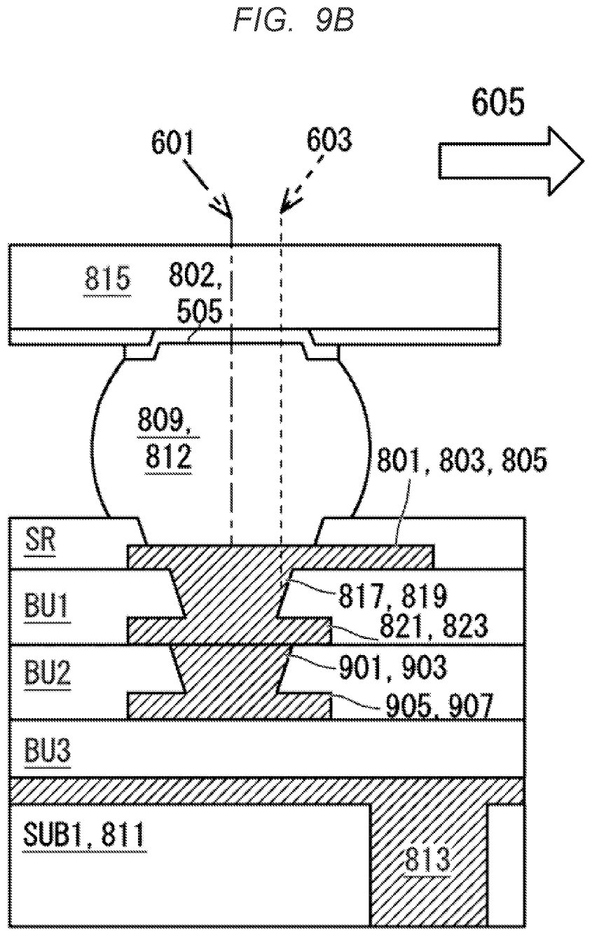

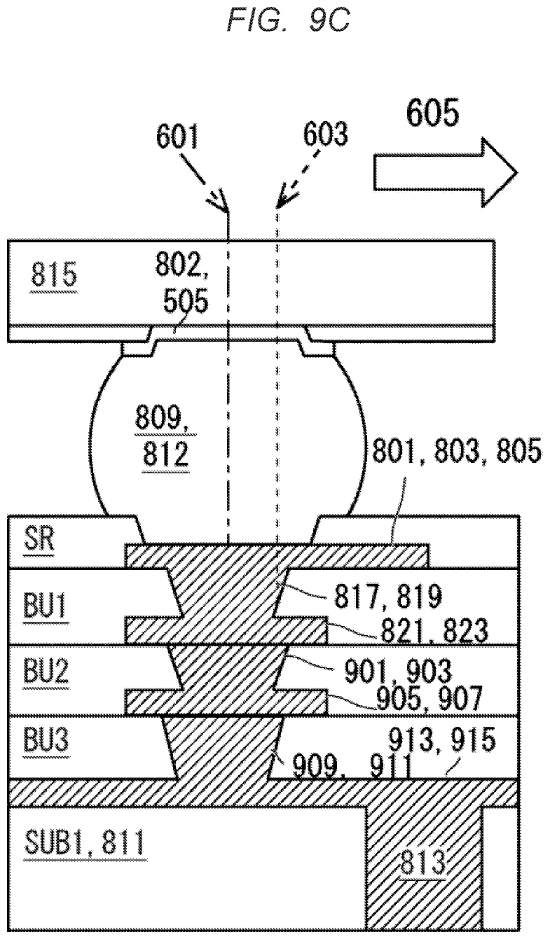

In addition to the “Pad on Via structure” shown in FIG. 9A in the first embodiment, there is a “Pad on Stacked Via structure” shown in FIG. 9B. The “Pad on Via structure” is a structure in which the land 801 overlaps the via wiring 817. The “Pad on Stacked Via structure” is a structure in which the second-layer via wiring 901 is stacked on the first-layer via wiring 817, and further, the land 801 is stacked on the first-layer via wiring 817. In the second embodiment, this “Pad on Stacked Via structure” is described.

As shown in FIG. 9B, the wiring substrate SUB1 has a plurality of wiring layers. For example, four wiring layers are formed on one side of the core layer. In that case, the insulating layers formed on one side are three layers BU1, BU2, and BU3.

As shown in FIG. 9B, the wiring substrate SUB1 has a first wiring layer 803, a first insulating layer BU1 located below the first wiring layer 803, and a second wiring layer 821 located below the first insulating layer BU1. Furthermore, the wiring substrate SUB1 has a second insulating layer BU2 located below the second wiring layer 821, and a third wiring layer 905 located below the second insulating layer BU2. Moreover, the wiring substrate SUB1 has an insulating film SR on the first wiring layer 803, and a plurality of lands 801 provided in the first wiring layer 803. The wiring substrate SUB1 has a plurality of first-layer via wirings 817 provided in the first insulating layer BU1, and a plurality of second wirings provided in the second wiring layer 821 and respectively connected with the plurality of lands 801 through the plurality of first-layer via wirings 817. Furthermore, the wiring substrate SUB1 has a plurality of second-layer via wirings 901 provided in the second insulating layer BU2, and a plurality of third wirings provided in the third wiring layer 905 and respectively connected with the plurality of second wirings through the plurality of second-layer via wirings 901.

The plurality of second wirings includes a second-layer first wiring electrically connected with the first land through the first via wiring of the plurality of first-layer via wirings 817, and a second-layer second wiring 823 electrically connected with the second land 805 through the second via wiring 819 of the plurality of first-layer via wirings 817.

The plurality of third wirings includes a third-layer first wiring electrically connected with the second-layer first wiring through the first via wiring of the plurality of second layer via wirings 901, and a third-layer second wiring 907 electrically connected with the second-layer second wiring 823 through the second via wiring 903 of the plurality of second-layer via wirings.

The second electrode pad 505, the second bump 812, the second land 805, the second via wiring 819 of the plurality of first-layer via wirings, the second-layer second wiring 823, the second via wiring 903 of the plurality of second-layer via wirings, and the third-layer second wiring 907 overlap with each other, in cross-sectional view.

In cross-sectional view, the center 603 of the second land is shifted in a direction 605 from the center 601 of the opening portion, which exposes a part of the second land, of the insulating film SR toward the center of the semiconductor chip.

As described above, in the structure shown in FIG. 9B (Pad on Stacked Via structure), the land 801 which is the first wiring (especially, the part of the first wiring to which the bump 812 is bonded) overlaps not only with the first-layer via wiring 817 but also with the second-layer via wiring 901. Therefore, in the case of the structure shown in FIG. 9B, the crack is more likely to occur than in the structure shown in FIG. 9A (Pad on Via structure). However, the structure disclosed herein is effective even in the structure shown in FIG. 9B.

### (Description of Connection Between Wiring Substrate and Semiconductor Chip According to Third Embodiment)

In addition to the structure shown in FIG. 9A as described in the first embodiment and the structure shown in FIG. 9B as described in the second embodiment, there is a structure shown in FIG. 9C. In this structure, as shown in FIG. 9C, the land 801, which is the first wiring provided in the uppermost wiring layer 803, is electrically connected with the fourth wiring provided in the fourth wiring layer 913 located on the upper surface of the core layer 811, through the first-layer via wiring 817, the second-layer via wiring 901, and the third-layer via wiring 909. The land 801, the first-layer via wiring 817, the second-layer via wiring 901, the third-layer via wiring 909, and the fourth wiring layer overlap with each other, as shown in FIG. 9C. Furthermore, as shown in FIG. 9C, the wiring substrate SUB1 has the third insulating layer BU3 located below the third wiring layer 905, the fourth wiring layer 913 located below the third insulating layer BU3, and the core layer 811 located below the fourth wiring layer 913. The wiring substrate SUB1 has a plurality of third-layer via wirings 909 provided in the third insulating layer BU3, and a plurality of fourth wirings provided in the fourth wiring layer 913 and connected with plurality of third wiring layers 905 through the plurality of third-layer via wirings 909. Additionally, due to its structural symmetry, the wiring substrate SUB1 has a fifth wiring layer located below the core layer 811, a fourth insulating layer located below the fifth wiring layer, a sixth wiring layer located below the fourth insulating layer, a fifth insulating layer located below the sixth wiring layer, a seventh wiring layer located below the fifth insulating layer, a sixth insulating layer located below the seventh wiring layer, and an eighth wiring layer located below the sixth insulating layer. The structure shown in FIG. 4 is a six-layer wiring structure, but in this embodiment, an eight-layer wiring structure is shown.

The plurality of fourth wirings includes a fourth-layer first wiring electrically connected with a third-layer first wiring through the first via wiring of the plurality of third-layer via wirings 909, and a fourth-layer second wiring electrically connected with a third-layer second wiring 907 through the second via wiring 911 of the plurality of third-layer via wirings.

Then, the second electrode pad 505, the second bump 812, the second land 805, the second via wiring 819 of the plurality of first-layer via wirings, the second-layer second wiring 823, the second via wiring 903 of the plurality of second-layer via wirings, the third-layer second wiring 907, the second via wiring 911 of the plurality of third-layer via wirings, and the fourth-layer second wiring 915 overlap with each other, in cross-sectional view.

The center 603 of the second land is shifted in the direction 605 from the center 601 of the opening portion, which exposes a part of the second land, of the insulating film SR toward the center of the semiconductor chip, in cross-sectional view.

As previously mentioned, in the structure shown in FIG. 9C, the land 801, which is the first wiring (specifically, the part of the first wiring on which the bump 812 is bonded), overlaps not only with the first-layer via wiring 817 and the second-layer via wiring 901 but also with the third-layer via wiring 909, and furthermore, is electrically connected with the fourth wiring formed on the upper surface of the core layer 811 through these via wirings 817, 901, 909. Therefore, in the structure shown in FIG. 9C, compared to the structures shown in FIGS. 9A and 9B, the aforementioned crack is more likely to occur. Rather, in the structure shown in FIG. 9C, since the land 801 is electrically connected with the fourth wiring formed on the upper surface of the core layer 811, which is thicker than the other insulating layers, it is most susceptible to the effects of expansion (or contraction) of the wiring substrate SUB1 due to heat treatment, compared to the structures shown in FIGS. 9A and 9B. That is, the aforementioned cracks are more pronounced in the structure shown in FIG. 9C than in the structures shown in FIGS. 9A and 9B. On the other hand, the structure disclosed herein is effective even in the structure shown in FIG. 9C.

As described above, although the invention made by the inventor has been specifically described based on the embodiment, the present invention is not limited to the embodiment already described, and it is needless to say that various modifications can be made without departing from the gist thereof.

What is claimed is:

1. A semiconductor device comprising:
a wiring substrate including a first wiring layer, an insulating layer located below said first wiring layer, a second wiring layer located below said insulating layer, an insulating film located above said first wiring layer, a plurality of lands provided in said first wiring layer, a plurality of via wirings provided in said insulating layer, and a plurality of wirings provided in said second wiring layer, said plurality of wirings being connected with said plurality of lands through said plurality of via wirings, respectively;
a semiconductor chip having a main surface, and a plurality of electrode pads arranged on said main surface, said semiconductor chip being mounted on said wiring substrate such that said main surface faces a front surface of said insulating film of said wiring substrate;
a plurality of bumps electrically connecting said plurality of lands with said plurality of electrode pads, respectively,
wherein said insulating film covers a peripheral portion of each of said plurality of lands so as to expose a part of each of said plurality of lands;
wherein, in plan view, said main surface of said semiconductor chip has:
a first side extending in a first direction;
a second side extending in a second direction crossing said first direction;
a third side extending in said first direction and facing said first side; and
a fourth side extending in said second direction and facing said second side,
wherein, in plan view, said main surface of said semiconductor chip includes:
a central region including a center of said semiconductor chip; and
a peripheral region arranged around said central region,
wherein, in plan view, said plurality of electrode pads is arranged along said first side and arranged in plural rows,
wherein said plurality of electrode pads includes:
a first electrode pad arranged in said central region; and
a second electrode pad arranged in said peripheral region,
wherein said plurality of lands includes:
a first land electrically connected with said first electrode pad through a first bump of said plurality of bumps; and
a second land electrically connected with said second electrode pad through a second bump of said plurality of bumps,
wherein said plurality of wirings includes:
a first wiring electrically connected with said first land through a first via wiring of said plurality of via wirings; and
a second wiring electrically connected with said second land through a second via wiring of said plurality of via wirings,
wherein, in cross-sectional view, said second electrode pad, said second bump, said second land, said second via wiring, and said second wiring overlap with each other, and
wherein, in plan view, a center of said second land is shifted in a direction from a center of an opening portion, which exposes said part of said second land, of said insulating film toward said center of said semiconductor chip.

2. A semiconductor device comprising:
a wiring substrate including a first wiring layer, a first insulating layer located below said first wiring layer, a second wiring layer located below said first insulating layer, a second insulating layer located below said second wiring layer, a third wiring layer located below said second insulating layer, an insulating film located above said first wiring layer, a plurality of lands, which is a first wiring, provided in said first wiring layer, a plurality of first-layer via wirings provided in said first insulating layer, a plurality of second wirings provided in said second wiring layer, a plurality of second-layer via wirings provided in said second insulating layer, and a plurality of third wirings provided in said third wiring layer, said plurality of second wirings being connected with said plurality of lands through said plurality of first-layer via wirings, respectively, and said plurality of third wirings being connected with said plurality of second wirings through said plurality of second-layer via wirings, respectively;
a semiconductor chip having a main surface, and a plurality of electrode pads arranged on said main surface, said semiconductor chip being mounted on said wiring substrate such that said main surface faces a front surface of said insulating film of said wiring substrate;
a plurality of bumps electrically connecting said plurality f lands with said plurality of electrode pads, respectively,
wherein said insulating film covers a peripheral portion of each of said plurality of lands so as to expose a part of each of said plurality of lands;
wherein, in plan view, said main surface of said semiconductor chip has:
a first side extending in a first direction;
a second side extending in a second direction crossing said first direction;
a third side extending in said first direction and facing said first side; and
a fourth side extending in said second direction and facing said second side,
wherein, in plan view, said main surface of said semiconductor chip includes:
a central region including a center of said semiconductor chip; and
a peripheral region arranged around said central region,
wherein, in plan view, said plurality of electrode pads is arranged along said first side and arranged in plural rows,
wherein said plurality of electrode pads includes:
a first electrode pad arranged in said central region; and
a second electrode pad arranged in said peripheral region,
wherein said plurality of lands includes:
a first land electrically connected with said first electrode pad through a first bump of said plurality of bumps; and
a second land electrically connected with said second electrode pad through a second bump of said plurality of bumps,
wherein said plurality of second wirings includes:
a second-layer first wiring electrically connected with said first land through a first via wiring of said plurality of first-layer via wirings; and
a second-layer second wiring electrically connected with said second land through a second via wiring of said plurality of first-layer via wirings,
wherein said plurality of third wirings includes:
a third-layer first wiring electrically connected with said second-layer first wiring through a first via wiring of said plurality of second-layer via wirings; and
a third-layer second wiring electrically connected with said second-layer second wiring through a second via wiring of said plurality of second-layer via wirings,
wherein, in cross-sectional view, said second electrode pad, said second bump, said second land, said second via wiring of said plurality of first-layer via wirings, said second-layer second wiring, said second via wiring of said plurality of second-layer via wirings, and said third-layer second wiring overlap with each other, and
wherein, in plan view, a center of said second land is shifted in a direction from a center of an opening portion, which exposes said part of said second land, of said insulating film toward said center of said semiconductor chip.

3. The semiconductor device according to claim 2, wherein an underfill resin is located between said semiconductor chip and said wiring substrate.

4. The semiconductor device according to claim 2,
wherein said wiring substrate has a third insulation layer located below said third wiring layer, a fourth wiring layer located below said third insulation layer, a core layer located below said fourth wiring layer, a fifth wiring layer located below said core layer, a fourth insulation layer located below said fifth wiring layer, a sixth wiring layer located below said fourth insulation layer, a fifth insulation layer located below said sixth wiring layer, a seventh wiring layer located below said fifth insulation layer, a sixth insulation layer located below said seventh wiring layer, an eighth wiring layer located below said sixth insulation layer, a plurality of third-layer via wirings provided in said third insulating layer, and a plurality of fourth wirings provided in said fourth wiring layer, said plurality of fourth wirings being connected with said plurality of third wirings through said plurality of third-layer via wirings, respectively;
wherein said plurality of fourth wirings includes:
a fourth-layer first wiring electrically connected with said third-layer first wiring through a first via wiring of said plurality of third-layer via wirings; and
a fourth-layer second wiring electrically connected with said third-layer second wiring through a second via wiring of said plurality of third-layer via wirings, and
wherein, in cross-sectional view, said second electrode pad, said second bump, said second land, said second via wiring of said plurality of first-layer via wirings, said second-layer second wiring, said second via wiring of said plurality of second-layer via wirings, said third-layer second wiring, said second via wiring of said plurality of third-layer via wirings, and said fourth-layer second wiring overlap with each other.

5. The semiconductor device according to claim 2, wherein a shape in plan view of said second land is oval.

6. The semiconductor device according to claim 2, further comprising:
a cover member including a heat dissipation plate adhered to said front surface of said insulating film of said wiring substrate so as to cover said semiconductor chip.

7. The semiconductor device according to claim 2, wherein when it is assumed that said first side is “a” and that said second side is “b”, an area (D) of said central region is defined based on “D=(1/2×a)×(1/2×b)”.

8. The semiconductor device according to claim 2, wherein said center of said semiconductor chip is coaxial with a center of said wiring substrate.

9. A semiconductor device comprising:
a wiring substrate including a first wiring layer, a first insulating layer located below said first wiring layer, a second wiring layer located below said first insulating layer, a second insulating layer located below said second wiring layer, a third wiring layer located below said second insulating layer, a third insulating layer located below said third wiring layer, a fourth wiring layer located below said third insulating layer, a core layer located below said fourth wiring layer, an insulating film located above said first wiring layer, a plurality of lands, which is a first wiring, provided in said first wiring layer, a plurality of first-layer via wirings provided in said first insulating layer, a plurality of second wirings provided in said second wiring layer, a plurality of second-layer via wirings provided in said second insulating layer, a plurality of third wirings provided in said third wiring layer, a plurality of third-layer via wirings provided in said third insulating layer, and a plurality of fourth wirings provided in said fourth wiring layer, said plurality of second wirings being connected with said plurality of lands through said plurality of first-layer via wirings, respectively, said plurality of third wirings being connected with said plurality of second wirings through said plurality of second-layer via wirings, respectively, and said plurality of fourth wirings being connected with said plurality of third wirings through said plurality of third-layer via wirings, respectively;
a semiconductor chip having a main surface, and a plurality of electrode pads arranged on said main surface, said semiconductor chip being mounted on said wiring substrate such that said main surface faces a front surface of said insulating film of said wiring substrate;
connecting said a plurality of bumps electrically plurality lands with said plurality of electrode pads, respectively,
wherein said insulating film covers a peripheral portion of each of said plurality of lands so as to expose a part of each of said plurality of lands;
wherein, in plan view, said main surface of said semiconductor chip has:
a first side extending in a first direction;
a second side extending in a second direction crossing said first direction;
a third side extending in said first direction and facing said first side; and
a fourth side extending in said second direction and facing said second side,
wherein, in plan view, said main surface of said semiconductor chip includes:
a central region including a center of said semiconductor chip; and
a peripheral region arranged around said central region,
wherein, in plan view, said plurality of electrode pads is arranged along said first side and arranged in plural rows,
wherein said plurality of electrode pads includes:
a first electrode pad arranged in said central region; and
a second electrode pad arranged in said peripheral region,
wherein said plurality of lands includes:
a first land electrically connected with said first electrode pad through a first bump of said plurality of bumps; and
a second land electrically connected with said second electrode pad through a second bump of said plurality of bumps,
wherein said plurality of second wirings includes:
a second-layer first wiring electrically connected with said first land through a first via wiring of said plurality of first-layer via wirings; and
a second-layer second wiring electrically connected with said second land through a second via wiring of said plurality of first-layer via wirings,
wherein said plurality of third wirings includes:
a third-layer first wiring electrically connected with said second-layer first wiring through a first via wiring of said plurality of second-layer via wirings; and
a third-layer second wiring electrically connected with said second-layer second wiring through a second via wiring of said plurality of second-layer via wirings,
wherein said plurality of fourth wirings includes:
a fourth-layer first wiring electrically connected with said third-layer first wiring through a first via wiring of said plurality of third-layer via wirings; and
a fourth-layer second wiring electrically connected with said third-layer second wiring through a second via wiring of said plurality of third-layer via wirings,
wherein, in cross-sectional view, said second electrode pad, said second bump, said second land, said second via wiring of said plurality of first-layer via wirings, said second-layer second wiring, said second via wiring of said plurality of second-layer via wirings, said third-layer second wiring, said second via wiring of said plurality of third-layer via wirings, and said fourth-layer second wiring overlap with each other, and
wherein, in plan view, a center of said second land is shifted in a direction from a center of an opening portion, which exposes said part of said second land, of said insulating film toward said center of said semiconductor chip.
